(19) United States
(12) Patent Application Publication
(10) Pub. No.: US 2025/0231567 A1
(43) Pub. Date: Jul. 17, 2025

(54) APPARATUS FOR FACILITATING NAVIGATION OF A DEVICE

(71) Applicant: Cosma Pabouctsidis, Geneva (CH)

(72) Inventor: Cosma Pabouctsidis, Geneva (CH)

(21) Appl. No.: 19/029,369

(22) Filed: Jan. 17, 2025

Related U.S. Application Data
(60) Provisional application No. 63/621,929, filed on Jan. 17, 2024.

(51) Int. Cl. G05D 1/646; G01R 33/07; G05D 1/244; G05D 1/86; G05D 111/10; G05D 111/50

(52) U.S. Cl. CPC G05D 1/646; G01R 33/072; G05D 1/244; G05D 1/86; G05D 2111/10; G05D 2111/54

(57) ABSTRACT

The present disclosure provides an apparatus for facilitating navigation of a device. Further, the apparatus may include a sensor board comprising two or more sensors. Further, the two or more sensors include a first sensor and a second sensor. Further, the first sensor and the second sensor may be in line on a first plane and separated by a distance. Further, the two or more sensors may be configured to generate a first sensor data and a second sensor data. Further, the apparatus may include a processing device communicatively coupled with the sensor board. Further, the processing device may be configured to analyze the first sensor data and the second sensor data. Further, the processing device may be configured to generate a navigation data. Further, the apparatus may include a communication device. Further, the communication device may be configured to transmit the navigation data to the device.

### FIELD OF DISCLOSURE

Generally, the present invention relates to data processing. More specifically, the present invention is methods, systems, apparatuses, and devices for facilitating navigation of a device.

### BACKGROUND

Traditional magnetic track-following sensors in mobile robots employ a single row of Hall sensors to detect the lateral position of a magnetic tape relative to the sensor. Current systems typically use a Proportional-Integral-Derivative (PID) control loop to generate a steering signal based on the lateral deviation of the tape from the sensor's center. This approach, while effective, is inherently reactive, relying on deviations to occur before corrective actions are initiated. Such systems therefore lack the capability to anticipate the robot's path and cannot provide precise positional feedback essential for high-speed operations.

Therefore, there is a need for improved methods, systems, apparatuses, and devices for facilitating mobile robot navigation using dual row hall sensors that may overcome one or more of the above-mentioned problems and/or limitations.

### SUMMARY OF DISCLOSURE

This summary is provided to introduce a selection of concepts in a simplified form, that are further described below in the Detailed Description. This summary is not intended to identify key features or essential features of the claimed subject matter. Nor is this summary intended to be used to limit the claimed subject matter's scope.

The present disclosure provides an apparatus for facilitating navigation of a device. Further, the apparatus may include a sensor board comprising two or more sensors. Further, the two or more sensors include a first sensor and a second sensor. Further, the first sensor and the second sensor may be in line on a first plane and separated by a distance. Further, the first sensor may be configured to generate a first sensor data based on monitoring of a characteristic of a first portion of a track. Further, the second sensor may be configured to generate a second sensor data based on monitoring of the characteristic of a second portion of the track. Further, the first portion of the track and second portion of the track may be in line along a length of the track. Further, the apparatus may include a processing device communicatively coupled with the sensor board. Further, the processing device may be configured to analyze the first sensor data and the second sensor data. Further, the processing device may be configured to generate a navigation data based on the analyzing. Further, the navigation data determines a movement of the device in accordance with the track. Further, the apparatus may include a communication device communicatively coupled with the processing device. Further, the communication device may be configured to transmit the navigation data to the device.

The present disclosure provides an apparatus for facilitating navigation of a device. Further, the apparatus may include a sensor board comprising two or more magnetic sensors. Further, the two or more magnetic sensors include a first sensor and a second sensor. Further, the first sensor and the second sensor may be in line on a first plane and separated by a distance. Further, the first sensor may be configured to generate a first sensor data based on monitoring of a magnetic field strength of a first magnetic field associated with a first portion of a magnetic track. Further, the second sensor may be configured to generate a second sensor data based on monitoring of the magnetic field strength of a second magnetic field associated with a second portion of the magnetic track. Further, the first portion of the magnetic track and second portion of the magnetic track may be in line along a length of the magnetic track. Further, the apparatus may include a processing device communicatively coupled with the sensor board. Further, the processing device may be configured to analyze the first sensor data and the second sensor data. Further, the processing device may be configured to generate a navigation data based on the analyzing. Further, the navigation data determines a movement of the device in accordance with the track. Further, the apparatus may include a communication device communicatively coupled with the processing device. Further, the communication device may be configured to transmit the navigation data to the device.

The present disclosure provides an apparatus for facilitating navigation of a device. Further, the apparatus may include a sensor board. Further, the sensor board may include two or more magnetic sensors. Further, the two or more magnetic sensors include a first sensor and a second sensor. Further, the first sensor and the second sensor may be in line on a first plane and separated by a distance. Further, the first sensor may be configured to generate a first sensor data based on monitoring of a magnetic field strength of a first magnetic field associated with a first portion of a magnetic track. Further, the second sensor may be configured to generate a second sensor data based on monitoring of the magnetic field strength of a second magnetic field associated with a second portion of the magnetic track. Further, the first portion of the magnetic track and second portion of the magnetic track may be in line along a length of the magnetic track. Further, the sensor board may include an electromagnetic coil which may be configured to generate a third magnetic field proximal to each of the two or more sensors. Further, an actuation of the electromagnetic coil generates the third magnetic field. Further, the two or more sensors may be further configured to generate a calibration data based on the third magnetic field. Further, the apparatus may include a processing device communicatively coupled with the sensor board. Further, the processing device may be configured to analyze the calibration data. Further, the processing device may be configured to determine a sensor status based on analyzing of the calibration data. Further, the sensor status indicates an accuracy corresponding to each of the two or more sensors. Further, the processing device may be configured to analyze the first sensor data and the second sensor data. Further, the processing device may be configured to generate a navigation data based on the analyzing. Further, the navigation data determines a movement of the device in accordance with the track. Further, the apparatus may include a communication device communicatively coupled with the processing device. Further, the communication device may be configured to transmit the navigation data to the device.

Both the foregoing summary and the following detailed description provide examples and are explanatory only. Accordingly, the foregoing summary and the following detailed description should not be considered to be restrictive. Further, features or variations may be provided in addition to those set forth herein. For example, embodiments may be directed to various feature combinations and sub-combinations described in the detailed description.

### BRIEF DESCRIPTIONS OF DRAWINGS

The accompanying drawings, which are incorporated in and constitute a part of this disclosure, illustrate various embodiments of the present disclosure. The drawings contain representations of various trademarks and copyrights owned by the Applicants. In addition, the drawings may contain other marks owned by third parties and are being used for illustrative purposes only. All rights to various trademarks and copyrights represented herein, except those belonging to their respective owners, are vested in and the property of the applicants. The applicants retain and reserve all rights in their trademarks and copyrights included herein, and grant permission to reproduce the material only in connection with reproduction of the granted patent and for no other purpose.

Furthermore, the drawings may contain text or captions that may explain certain embodiments of the present disclosure. This text is included for illustrative, non-limiting, explanatory purposes of certain embodiments detailed in the present disclosure.

FIG. 1 is an illustration of a magnetic line-following automatic guided vehicle and its key components, in accordance with some embodiments.

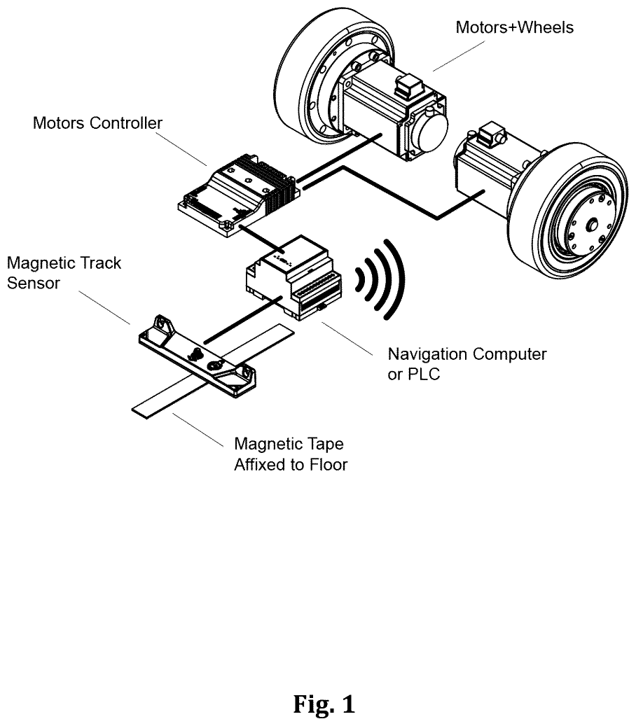

FIG. 2 is a block diagram of a computing device 200 for implementing the methods disclosed herein, in accordance with some embodiments.

FIG. 3 illustrates a block diagram of an apparatus 300 for facilitating navigation of a device, in accordance with some embodiments.

FIG. 4 illustrates a block diagram of the apparatus 400 for facilitating navigation of a device, in accordance with some embodiments.

FIG. 5 illustrate a block diagram of the apparatus 500 for facilitating navigation of a device, in accordance with some embodiments.

FIG. 6 illustrates an apparatus 600 for angle measurement with dual row sensing, in accordance with some embodiments.

FIG. 7 illustrates enhanced distance measurement with phase-shifted dual-row magnetic sensing using the apparatus 700, in accordance with some embodiments.

FIG. 8 illustrates position measurement of point magnetic sources 806 with the dual row hall sensors, in accordance with some embodiments.

FIG. 9 illustrates a dual-row magnetic track sensor 900, in accordance with some embodiments.

FIG. 10 is a block diagram of a system 1000 for facilitating mobile robot 1006 navigation using dual row hall sensors, in accordance with some embodiments.

FIG. 11 is a flow chart of a method 1100 for facilitating mobile robot navigation using dual row hall sensors, in accordance with some embodiments.

### DETAILED DESCRIPTION OF DISCLOSURE

As a preliminary matter, it will readily be understood by one having ordinary skill in the relevant art that the present disclosure has broad utility and application. As should be understood, any embodiment may incorporate only one or a plurality of the above-disclosed aspects of the disclosure and may further incorporate only one or a plurality of the above-disclosed features. Furthermore, any embodiment discussed and identified as being “preferred” is considered to be part of a best mode contemplated for carrying out the embodiments of the present disclosure. Other embodiments also may be discussed for additional illustrative purposes in providing a full and enabling disclosure. Moreover, many embodiments, such as adaptations, variations, modifications, and equivalent arrangements, will be implicitly disclosed by the embodiments described herein and fall within the scope of the present disclosure.

Accordingly, while embodiments are described herein in detail in relation to one or more embodiments, it is to be understood that this disclosure is illustrative and exemplary of the present disclosure, and are made merely for the purposes of providing a full and enabling disclosure. The detailed disclosure herein of one or more embodiments is not intended, nor is to be construed, to limit the scope of patent protection afforded in any claim of a patent issuing here from, which scope is to be defined by the claims and the equivalents thereof. It is not intended that the scope of patent protection be defined by reading into any claim limitation found herein and/or issuing here from that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present disclosure. Accordingly, it is intended that the scope of patent protection is to be defined by the issued claim(s) rather than the description set forth herein.

Additionally, it is important to note that each term used herein refers to that which an ordinary artisan would understand such term to mean based on the contextual use of such term herein. To the extent that the meaning of a term used herein—as understood by the ordinary artisan based on the contextual use of such term—differs in any way from any particular dictionary definition of such term, it is intended that the meaning of the term as understood by the ordinary artisan should prevail.

Furthermore, it is important to note that, as used herein, “a” and “an” each generally denotes “at least one,” but does not exclude a plurality unless the contextual use dictates otherwise. When used herein to join a list of items, “or” denotes “at least one of the items,” but does not exclude a plurality of items of the list. Finally, when used herein to join a list of items, “and” denotes “all of the items of the list.”

The following detailed description refers to the accompanying drawings. Wherever possible, the same reference numbers are used in the drawings and the following description to refer to the same or similar elements. While many embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the claims found herein and/or issuing here from. The present disclosure contains headers. It should be understood that these headers are used as references and are not to be construed as limiting upon the subjected matter disclosed under the header.

The present disclosure includes many aspects and features. Moreover, while many aspects and features relate to, and are described in the context of the disclosed use cases, embodiments of the present disclosure are not limited to use only in this context.

### Overview

Disclosed herein is a system for facilitating mobile robot navigation using dual row hall sensors, in accordance with some embodiments. Accordingly, the system may include a communication device configured for receiving a plurality of sensor data from a plurality of sensors. Further, the communication device may be configured for transmitting a steering command to the mobile robot. Further, the system may include a processing device configured for analyzing the plurality of sensor data. Further, the processing device may be configured for generating a position information associated with a magnetic tape based on the analyzing of the plurality of sensor data. Further, the processing device may be configured for processing the position information based on robot information associated with the mobile robot. Further, the robot information may include mechanical dimensions of the robot. Further, the processing device may be configured to generate the steering command based on the processing.

Further disclosed herein is a method for facilitating mobile robot navigation using dual row hall sensors, in accordance with some embodiments. Accordingly, the method may include receiving, using a communication device, a plurality of sensor data from a plurality of sensors. Further, the method may include analyzing, using a processing device, the plurality of sensor data. Further, the method may include generating, using the processing device, a position information associated with a magnetic tape based on the analyzing of the plurality of sensor data. Further, the method may include processing, using the processing device, the position information based on robot information associated with the mobile robot. Further, the method may include generating, using the processing device, a steering command based on the processing. Further, the method may include transmitting, using the communication device, the steering command to the mobile robot.

The present disclosure describes methods, systems, apparatuses, and devices for facilitating mobile robot navigation using dual row hall sensors. Further, the disclosed apparatus may include a magnetic track following sensor for mobile robots featuring dual rows of Hall sensors. Further, the disclosed apparatus detects the lateral position of a magnetic tape and its angle of intersection enabling the generation of a more accurate steering signal. This anticipates the robot's path, resulting in improved precision and stability. Additionally, the magnetic track following sensor (or sensor) may measure traveled distance and detect faults, offering a comprehensive solution for mobile robot navigation.

Further, the disclosed system may be a guidance system for mobile robots, particularly to a magnetic track following sensor system that enhances steering precision and stability by utilizing dual-row hall sensors.

Further, the disclosed apparatus may include a dual-row hall sensor array that allows for the detection of both the lateral position and the angle at which the magnetic tape intersects with the sensor.

Further, the disclosed apparatus may provide enhanced steering control by utilizing an angle information from the second row of sensors to calculate a more precise steering signal. Further, the disclosed apparatus may be configured to anticipate the robot's path based on mechanical dimensions, rather than merely reacting to deviations, leading to improved precision and stability. Further, the disclosed apparatus employs the angle information as a feedforward signal in the control loop. The increased steering precision permits higher operational speeds, enhancing the robot's efficiency and productivity along the track. Further, the disclosed apparatus may perform an accurate distance measurement. When used with magnetic tape having alternating polarity, the sensor array may precisely measure the robot's distance traveled. Further, this is achieved by detecting varying magnetic strength levels, similar to the function of a linear sin/cos sensor or a quadrature encoder. Further, the disclosed apparatus may be configured for determining the exact position of point sources like small cylindrical magnets or thin magnetic disks. Further, the disclosed apparatus may be configured for achieving high-precision positioning at specific points such as loading/unloading or charging stations. The second row of sensors offers redundancy, enhancing reliability. Further, the disclosed apparatus may detect faults or discrepancies compared to systems with a single sensor row.

This disclosed apparatus is particularly suitable for the mobile robots in industrial, commercial, and logistics environments where precise navigation and positioning are critical. Further, the disclosed apparatus offers significant improvements in terms of accuracy, reliability, and anticipatory control compared to existing single-row sensor systems. Further, a mobile robot that uses the sensor provided in the present disclosure may have a typical and quite specific system architecture.

Further, the disclosed apparatus may include the magnetic track following sensor comprising two parallel rows of Hall sensors, spaced apart at a predefined distance. This arrangement allows for simultaneous detection of both the lateral position and the angle of intersection of the magnetic tape with respect to the sensor. Further, the disclosed apparatus may process the sensor's output to determine the exact position and orientation of the tape, which is then used to compute a precise steering signal. Further, a control algorithm, enhanced by the angle information, anticipates the robot's path, allowing for smoother and more accurate navigation.

Further, the sensor's ability to measure distance through the alternating magnetic polarity of the tape adds an additional layer of functionality, making it an all-encompassing solution for mobile robot navigation. Further, the angle detection capability is used to generate a steering signal based on the mechanical dimensions of the robot, allowing for anticipatory path following.

Further, the disclosed apparatus may be configured for measuring the distance traveled by the robot when used with magnetic tape having alternating polarity. Further, the disclosed apparatus may be configured for precisely determining the position of point magnetic sources for high-precision positioning tasks. Further, the second row of sensors provides redundancy and fault detection capabilities.

Further the disclosed apparatus may include:
1. Magnetic Tape: A strip affixed to the floor that provides the path or “track” for the automatic guided vehicle to follow.
2. Magnetic Track Sensor: Positioned above the tape, it detects the tape's exact position and angle. The sensor then transmits this data (via various interfaces, such as analog, serial, or fieldbus) to the navigation computer or PLC.
3. Navigation Computer/PLC: Receives the sensor data, computes the necessary trajectory adjustments, and ensures the automatic guided vehicle stays aligned with the track. It determines the vehicle's speed and direction commands.
4. Motor Controller: Takes the requested speed/direction commands from the navigation computer or PLC and supplies the appropriate power signals to the motors.
5. Motors+Wheels: The drive mechanism that propels the automatic guided vehicle according to the motor controller's instructions, enabling precise movements along the magnetic track.

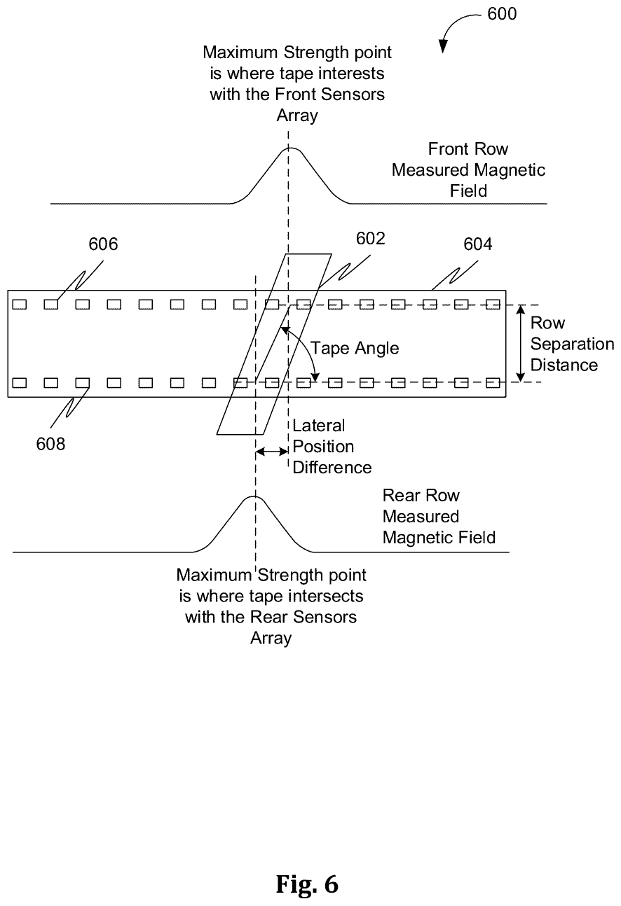

FIG. 6 illustrates an apparatus for angle measurement with dual row sensing, in accordance with some embodiments. Accordingly, the apparatus 600 may be configured for determining the angle of magnetic tape 602 intersection using a dual-row hall sensor 604. Further, the dual row hall sensor 604 may include two separate arrays of individual hall sensors: a front array 606 and a rear array 608, which are positioned at a fixed row separation distance apart on the same plane. Further, a magnetic tape 602 affixed on the floor intersects with both sensor arrays at different points, as indicated by vertical dashed lines in FIG. 6. The vertical dashed lines culminate at peaks on the respective magnetic field graphs above each array, marking the points of maximum strength where the magnetic tape 602 intersects with each array. Further, the apparatus 600 may measure the tape angle, which is represented by a solid line between the two points of intersection on the front sensor array 606 and rear sensor array 608. The lateral position difference between these intersection points on the two arrays provides data that, when combined with the known row separation distance, allows for the calculation of the intersection angle of the magnetic tape 602. The angle measurement capability provided is a significant improvement over the single-array method, as it enables the sensor to determine not only the lateral position but also the orientation of the magnetic tape 602 relative to the sensor. The data may be used to generate more accurate steering signals, anticipating the robot's trajectory and improving navigational precision. The figure emphasizes the dual-row sensor's ability to provide richer positional information, which is essential for the advanced control of mobile robots.

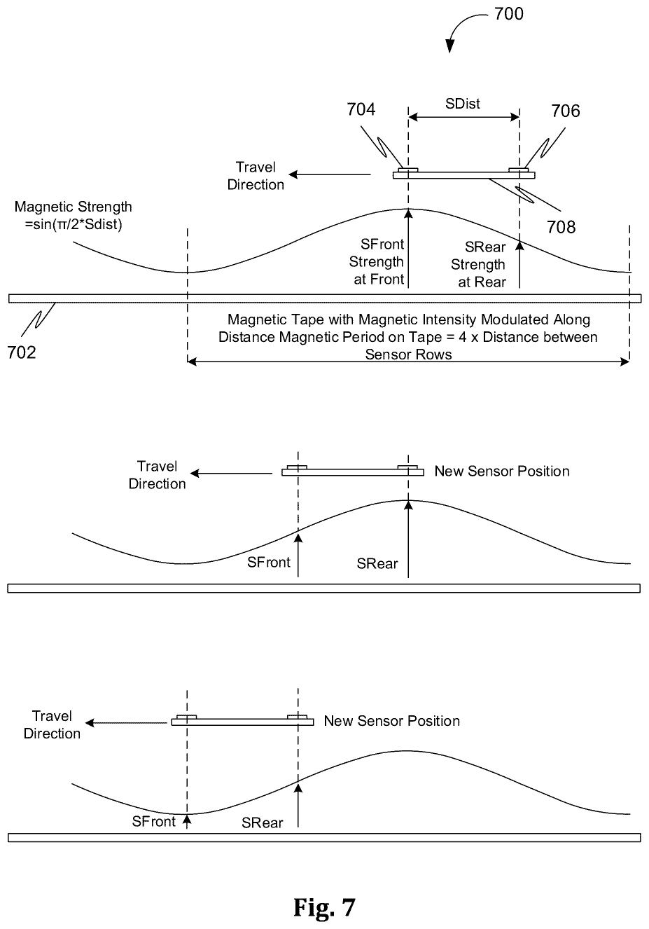

FIG. 7 illustrates enhanced distance measurement with phase-shifted dual-row magnetic sensing using the apparatus 700, in accordance with some embodiments. Accordingly, the apparatus 700 may include a dual-row sensor setup 708 on the magnetic tape 702 with a modulated magnetic field, designed to encode linear position similarly to sin/cos sensors on rotary encoders. As the robot travels from right to left, the front row of sensors 704 reads the magnetic field strength, producing a sinusoidal output that correlates with the robot's position along the tape 702. This is represented by the “SFront Strength at Front” curve in the front graph. The rear row of sensors 706, positioned a quarter period (90 degrees phase shift) away from the front row, reads a cosine wave, depicted by the “SRear Strength at Rear” curve in the rear graph. The phase shift between the front and rear sensors is intentional, mirroring the sin/cos relationship found in rotary encoders, but adapted for linear measurement. The formula “Magnetic Strength=sin (π/2*SDist)” for the front sensors, with the rear sensors capturing the cosine equivalent, enables the apparatus 700 to calculate the robot's exact position within the magnetic period. For extended travel distances, the apparatus 700 may tally the number of complete magnetic cycles (full sine and cosine waves) traversed, providing accurate long-distance odometry. The apparatus 700 may determine precise absolute positions within each magnetic field alternation, coupled with cycle counting for longer distances, making it an exceptionally accurate and reliable apparatus for linear position tracking in robotic applications.

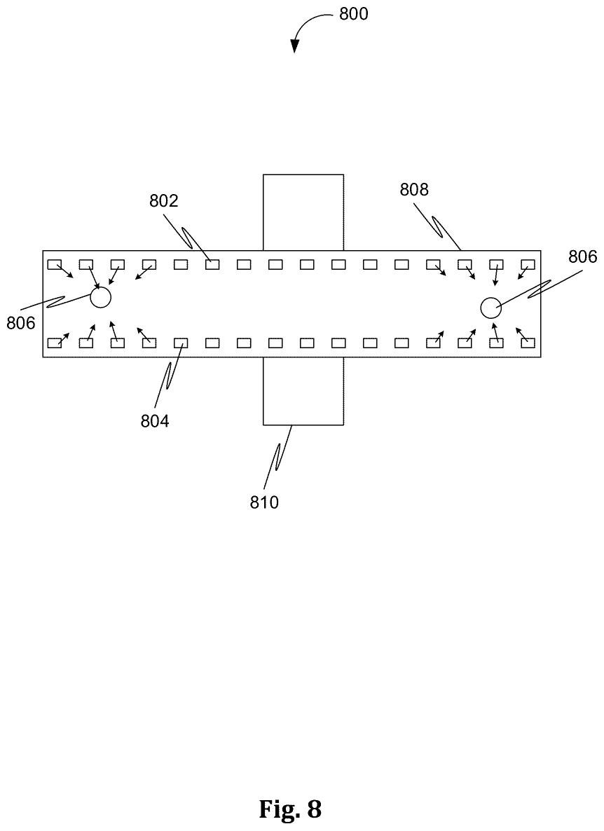

FIG. 8 illustrates position measurement of point magnetic sources 806 with the dual row hall sensors, in accordance with some embodiments. Accordingly, the dual-row hall sensor 808 may be configured to accurately identify the position of point magnetic sources 806 against a background of magnetic tape 810. The point sources 806 may be either small cylindrical magnets that fit into holes drilled into the floor or thin disc-shaped magnets. The point magnetic sources 806 are designed with the opposite polarity to the magnetic tape 810 used for track following, allowing the apparatus 800 to clearly distinguish between the general path defined by the tape 810 and the specific points marked by the point magnetic sources 806. In the illustration, the front sensor array 802 and rear sensor array 804 may detect the magnetic field generated by the point magnetic sources 806. The strength of the magnetic field at each sensor may be indicated by the length of the arrows pointing to the sensors, with longer arrows representing stronger fields, suggesting closer proximity to the point magnetic sources 806.

The dual hall sensor arrays 808 may detect variations in the magnetic field strength, enabling the apparatus 800 to calculate the exact position of the point magnetic sources 806 with respect to the sensors. The feature is particularly useful for precise navigation and positioning in applications where accurate localization is essential, such as robotic systems that must align with or travel to specific points for tasks like material handling, docking, or charging.

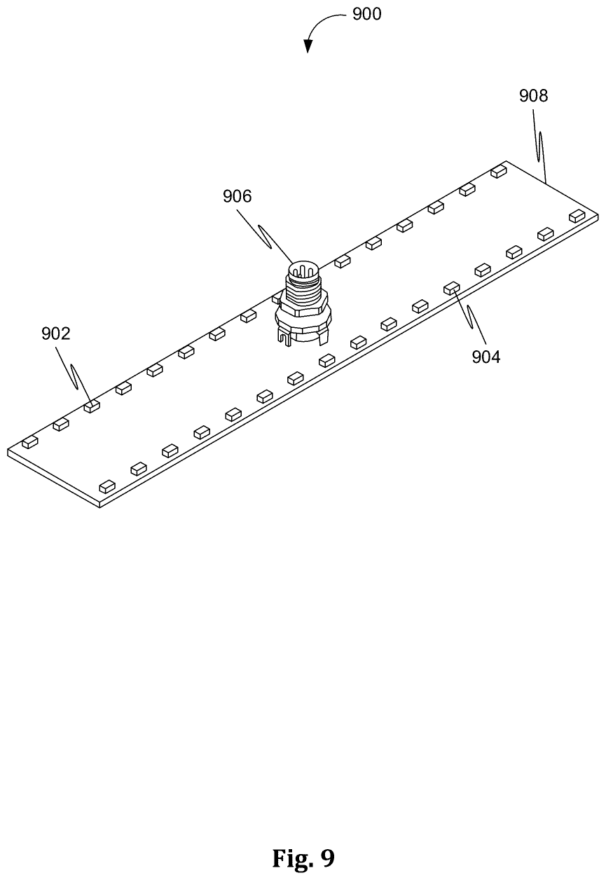

FIG. 9 illustrates a dual-row magnetic track sensor 900, in accordance with some embodiments. Accordingly, the dual-row magnetic track sensor 900 (or the dual row hall sensor) may be mounted on a printed circuit board 908 (PCB). The front sensor array 902 and the rear sensor array 904, each consist of multiple Hall sensors arranged in a linear configuration. The front sensor array 902 and the rear sensor 904 array are positioned along the length of the PCB 908, providing the capability to detect magnetic fields below the sensor assembly. At the center of the PCB 908, the dual row magnetic track sensor 900 may include a power and data connector 906 which provides the necessary electrical connections for the sensor to receive power and to interface with a control system of the mobile robot for data communication. The front sensor array 902 may be positioned closer to the edge of the PCB 908, while the rear sensor array 904 is aligned correspondingly below it. This dual-array configuration allows the sensor to detect the lateral position of a magnetic guide tape as well as the angle at which the tape intersects with the sensor array. Each hall sensor in the arrays is represented by a square symbol, indicating their regular and equidistant placement along the PCB 908, for accurate detection and measurement of magnetic fields.

Further, the apparatus 900 may include a communication device configured for receiving a plurality of sensor data from a plurality of sensors. Further, the plurality of sensors may be comprised in at least one of the front sensor array and the rear sensor array. Further, the plurality of sensors may include hall sensors, motion sensors, proximity sensors, etc. Further, the communication device may be configured for transmitting a steering command to the mobile robot.

Further, the apparatus 900 may include a processing device configured for analyzing the plurality of sensor data. Further, the processing device may be configured for generating a position information associated with a magnetic tape based on the analyzing of the plurality of sensor data. Further, the position information may indicate a lateral position and an angle of intersection at which the magnetic tape intersects with the plurality of sensors. Further, the position information may represent a position and an orientation of the tape. Further, the processing device may be configured for processing the position information based on robot information associated with the mobile robot. Further, the robot information may include mechanical dimensions of the robot. Further, the processing device may be configured for generating the steering command based on the processing. Further, the steering command may guide the mobile robot to move.

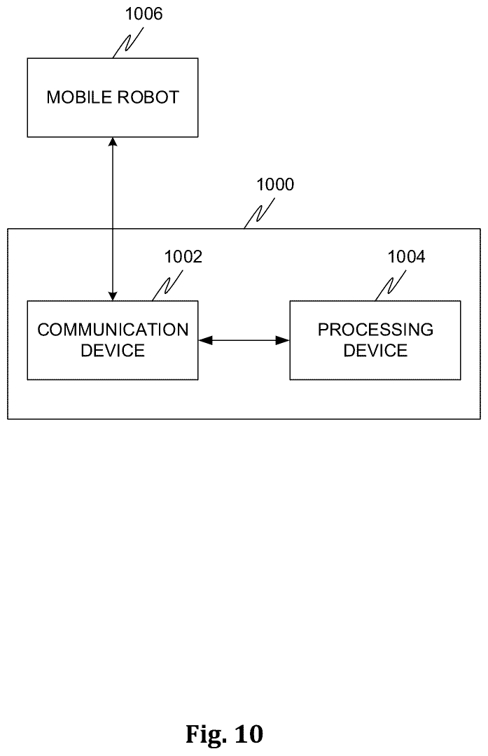

FIG. 10 is a block diagram of a system 1000 for facilitating mobile robot 1006 navigation using dual row hall sensors, in accordance with some embodiments. Accordingly, the system 1000 may include a communication device 1002 configured for receiving a plurality of sensor data from a plurality of sensors. Further, the plurality of sensors may be comprised in at least one of the front sensor array and the rear sensor array. Further, the plurality of sensors may include hall sensors, motion sensors, location sensors, proximity sensors, etc. Further, the communication device 1002 may be configured for transmitting a steering command to the mobile robot 1006.

Further, the system 1000 may include a processing device 1004 configured for analyzing the plurality of sensor data. Further, the processing device 1004 may be configured for generating a position information associated with a magnetic tape based on the analyzing of the plurality of sensor data. Further, the position information may indicate a lateral position and an angle of intersection at which the magnetic tape intersects with the plurality of sensors. Further, the position information may represent a position and an orientation of the tape. Further, the processing device 1004 may be configured for processing the position information based on robot information associated with the mobile robot 1006. Further, the robot information may include mechanical dimensions of the robot. Further, the processing device 1004 may be configured for generating the steering command based on the processing. Further, the steering command may guide the mobile robot 1006 to move.

Further, in some embodiments, the processing device 1004 may be configured for determining a robot movement information of the mobile robot 1006 based on analyzing of the plurality of sensor data and an area data associated with an area. Further, the mobile robot 1006 may navigate in the area. Further, the area data may include area dimensions. Further, the communication device may be configured for transmitting the robot movement information to at least one user device associated with a user. Further, the at least one user device may include a mobile, a tablet, a laptop, etc. Further, the user may include an individual, an institution, and an organization that may want to navigate the mobile robot 1006. Further, the robot movement information may include a location, a speed, a distance travelled, etc.

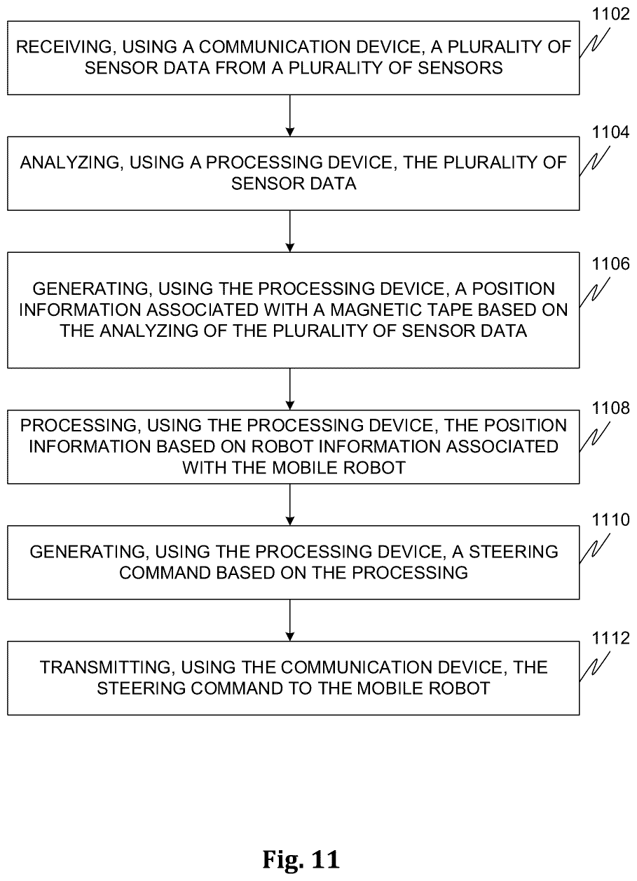

FIG. 11 is a flow chart of a method 1100 for facilitating mobile robot navigation using dual row hall sensors, in accordance with some embodiments. Accordingly, the method 1100 may include a step 1102 of receiving, using a communication device 1002, a plurality of sensor data from a plurality of sensors. Further, the plurality of sensors may be comprised in at least one of the front sensor array and the rear sensor array. Further, the plurality of sensors may include hall sensors, motion sensors, proximity sensors, etc.

Further, the method 1100 may include a step 1104 of analyzing, using a processing device 1004, the plurality of sensor data.

Further, the method 1100 may include a step 1106 of generating, using the processing device 1004, a position information associated with a magnetic tape based on the analyzing of the plurality of sensor data. Further, the position information may indicate a lateral position and an angle of intersection at which the magnetic tape intersects with the plurality of sensors. Further, the position information may represent a position and an orientation of the tape.

Further, the method 1100 may include a step 1108 of processing, using the processing device 1004, the position information based on robot information associated with the mobile robot. Further, the robot information may include mechanical dimensions of the robot.

Further, the method 1100 may include a step 1110 of generating, using the processing device 1004, a steering command based on the processing. Further, the steering command may guide the mobile robot to move.

Further, the method 1100 may include a step 1112 of transmitting, using the communication device 1002, the steering command to the mobile robot 1006.

Further, an online platform consistent with various embodiments of the present disclosure may also be included. By way of non-limiting example, the online platform may be hosted on a centralized server, such as, for example, a cloud computing service. The centralized server may communicate with other network entities, such as, for example, a mobile device (such as a smartphone, a laptop, a tablet computer, etc.), other electronic devices (such as desktop computers, server computers, etc.), databases, and sensors over a communication network, such as, but not limited to the Internet. Further, users of the online platform may include relevant parties such as, but not limited to, end-users, administrators, service providers, service consumers, and so on. Accordingly, in some instances, electronic devices operated by the one or more relevant parties may be in communication with the platform.

A user, such as the one or more relevant parties, may access online platform through a web based software application or browser. The web based software application may be embodied as, for example, but not be limited to, a website, a web application, a desktop application, and a mobile application compatible with a computing device 200.

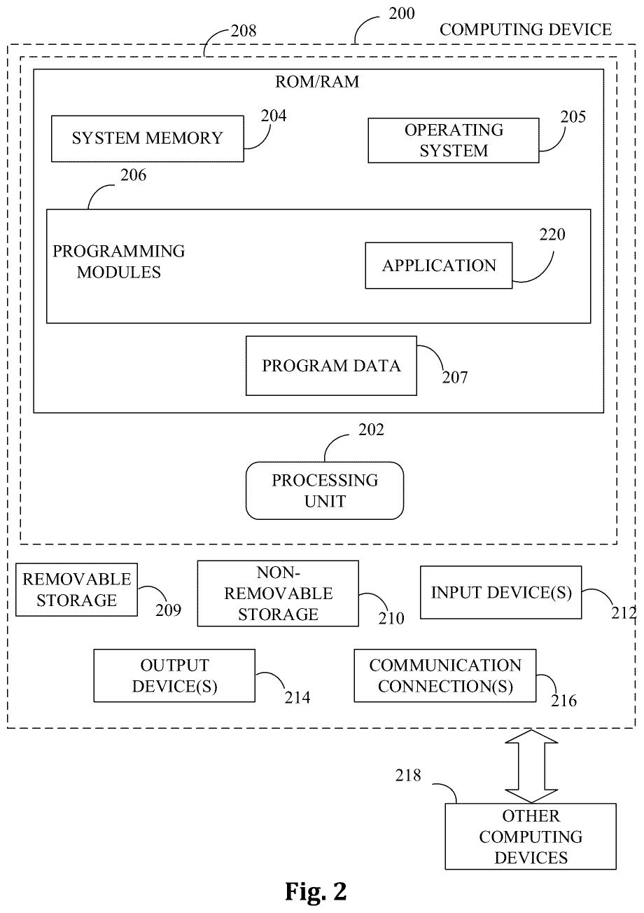

With reference to FIG. 2, a system consistent with an embodiment of the disclosure may include a computing device or cloud service, such as computing device 200. In a basic configuration, computing device 200 may include at least one processing unit 202 and a system memory 204.

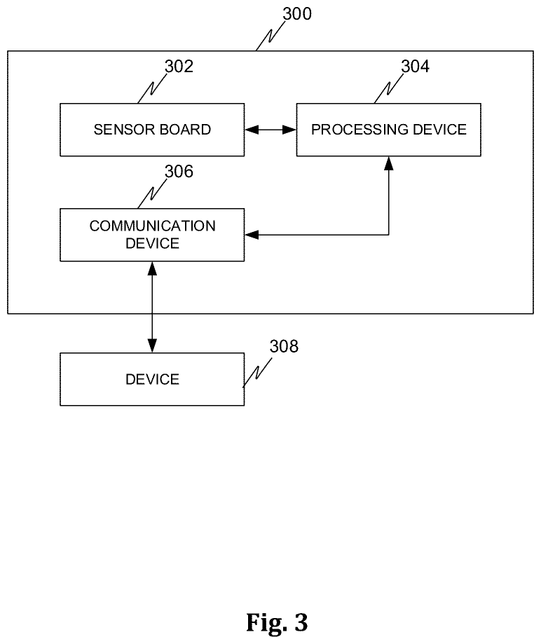

FIG. 3 illustrates a block diagram of an apparatus 300 for facilitating navigation of a device, in accordance with some embodiments.

In some embodiments, the device includes a mobile robotic device. In some embodiments, the navigation of device includes steering the device along a predefined path. In some embodiments, the navigation of the device facilitated based on generation of a steering data based on the track.

In some embodiments, the device includes an automated guided vehicle configured to move along the predefined path.

Accordingly, the apparatus 300 may include a sensor board 302 comprising two or more sensors.

In some embodiments, the sensor board 302 includes a printed circuit board.

Further, the two or more sensors include a first sensor and a second sensor.

In some embodiments, the two or more sensors include one or more of an optical sensor and a magnetic sensor.

Further, the first sensor and the second sensor may be in line on a first plane and separated by a distance. Further, the first sensor may be configured to generate a first sensor data based on monitoring of a characteristic of a first portion of a track.

In some embodiments, the track includes one or more of an optically visible tape, magnetic tape, and a magnetic strip affixed to the ground.

In some embodiments, the characteristic includes one or more of a width of the track, a magnetic field strength associated with the track.

Further, the second sensor may be configured to generate a second sensor data based on monitoring of the characteristic of a second portion of the track. Further, the first portion of the track and second portion of the track may be in line along a length of the track.

Further, the apparatus 300 may include a processing device 304 communicatively coupled with the sensor board 302.

In some embodiments, processing device may be an electronic device which may be configured to execute a set of instructions.

In some embodiments, the electronic device includes at least one of a navigation computer and a programmable logic computer. Further, the processing device 304 may be configured to analyze the first sensor data and the second sensor data. Further, the processing device 304 may be configured to generate a navigation data based on the analyzing. Further, the navigation data determine a movement of the device 308 in accordance with the track.

Further, the apparatus 300 may include a communication device 306 communicatively coupled with the processing device 304.

In some embodiments, the communication device 306 may be configured to one or more of receive and transmit a data. In some embodiments, one or more of the receiving and transmitting of the data may be wireless.

In some embodiments, one or more of the receiving and transmitting of the data may be based on a communication interface. Further, the communication interface may include at least one of an analog interface, a serial interface and a fieldbus.

Further the analog interface may be configured to perform at least one of transmitting and receiving based on a continuous signal representing a varying level of at least one of a voltage and current. Further, the serial interface may be configured to perform at least one of transmitting and receiving based on a single channel. Further, the fieldbus may be configured to perform at least one of transmitting and receiving based on a single cable.

Further, the communication device 306 may be configured to transmit the navigation data to the device 308.

In some embodiments, the processing device 304 may be further configured to determine an angle of intersection based on the analyzing of the first sensor data and the second sensor data. Further, the generation of navigation data may be based on the angle of intersection.

In some embodiments, each of the first sensor and the second sensor includes two or more sensor elements in a linear configuration.

In some embodiments, each of the two or more sensor elements includes of a sensor integrated circuit.

Further, each of the two or more sensor elements of the first sensor may be parallel to each of the two or more sensor elements of the second sensor.

In some embodiments, the first sensor includes a first magnetic sensor and the second sensor includes a second magnetic sensor. Further, the track includes of a magnetic track which may be configured to emit a magnetic field. Further, the first magnetic and the second magnetic may be configured to monitor the characteristic of the track based on the magnetic field emitted by the track.

In some embodiments, the characteristic may include a magnetic field strength of the magnetic field.

In some embodiments, the two or more sensors may be further configured to generate a sensor data based on detection of a track point proximal to the track.

In some embodiments, the track point includes an optically visible track point, a magnetic disk, and a magnetic point.

Further, the track point includes a unique characteristic. Further, the generation of the navigation data may be further based on the sensor data.

Further, the navigation data may include at least one of a robot speed data and a direction data. Further, the robot speed data determine a speed of the mobile robot in accordance with the track. Further, the direction data determine a direction of the mobile robot in accordance with the track. In some embodiments, the processing device may be communicatively coupled to a motor controller device configured for generating a power signal directed for navigating the device based on at least one of the robot speed data and the direction data.

In some embodiments the motor controller device may further be communicatively coupled to a motor device configured for initiating a rotary motion in a wheel associated with the device in relation to the track. Further, the motor device may include a plurality of motor devices associated with a plurality of wheels.

In some embodiments, the sensor board may be on a second spatial plane. Further, the track may be on a third spatial plane. Further, the second plane and the third plane may be orthogonal.

In some embodiments, each of the first sensor and the second sensor includes a magnetic sensor. Further, the track includes a magnetic track which may be configured to emit an alternating magnetic field.

In some embodiments, the magnitude of the alternating magnetic field may be based on a mathematical function.

Further, the magnitude of the alternating magnetic field may be based on the distance. Further, the first sensor may be configured to generate first sensor data based on a first magnetic field strength. Further, the second sensor may be configured to generate the second sensor data based on a second magnetic field strength. Further, the processing device 304 may be configured to generate a distance travel data based on the first sensor data and the second sensor data. Further, the distance travel data may be indicative of a distance travelled by the device.

In some embodiments, the two or more sensors include two or more optical sensors. Further, the track includes an optical characteristic. Further, the two or more optical sensors may be configured to monitor the optical characteristic.

In some embodiments, the first sensor data corresponds to a first width of the track and the second sensor data corresponds to a second width of the track. Further, the generation of navigation data may be based on a criterion associated with the first width and the second width.

In some embodiments, the criterion includes a difference threshold associated with a difference between the first width and the second width.

In some embodiments, the processing device 304 may be further configured to determine a lateral position of the device in relation to the track based on the analysis. Further, the generation of the navigation data may be based on the lateral position.

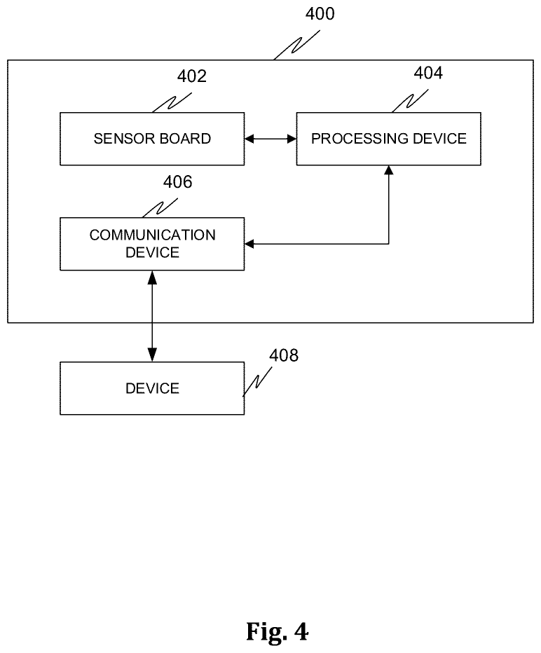

FIG. 4 illustrates a block diagram of the apparatus 400 for facilitating navigation of a device, in accordance with some embodiments.

Accordingly, the apparatus 300 may include a sensor board 302 comprising two or more magnetic sensors.

In some embodiments, the two or more magnetic sensors may include two or more hall-effect sensors.

Further, the two or more magnetic sensors includes a first sensor and a second sensor. Further, the first sensor and the second sensor may be in line on a first plane and separated by a distance. Further, the first sensor may be configured to generate a first sensor data based on monitoring of a magnetic field strength of a first magnetic field associated with a first portion of a magnetic track. Further, the second sensor may be configured to generate a second sensor data based on monitoring of the magnetic field strength of a second magnetic field associated with a second portion of the magnetic track. Further, the first portion of the magnetic track and second portion of the magnetic track may be in line along a length of the magnetic track.

Further, the apparatus 400 may include a processing device 404 communicatively coupled with the sensor board 402. Further, the processing device 404 may be configured to analyze the first sensor data and the second sensor data. Further, the processing device 404 may be configured to generate a navigation data based on the analyzing. Further, the navigation data determine a movement of the device in accordance with the track.

In some embodiments, the processing device 404 includes at least one of a navigation computer and a programmable logic computer. Further, the navigation data may include at least one of a robot speed data and a direction data. Further, the robot speed data determine a speed of the mobile robot in accordance with the track. Further, the direction data determine a direction of the mobile robot in accordance with the track.

Further, the apparatus 400 may include a communication device 406 communicatively coupled with the processing device 404. Further, the communication device 406 may be configured to transmit the navigation data to the device 408.

In some embodiments, the sensor board 402 further includes an electromagnetic coil which may be configured to generate a third magnetic field proximal to each of the two or more sensors.

In some embodiments, the electromagnetic coil may be under the each of the two or more magnetic sensors. In some embodiments, the electromagnetic coil includes a printed circuit coil electromagnet.

Further, an actuation of the electromagnetic coil generates the third magnetic field. Further, the two or more sensors may be further configured to generate a calibration data based on the third magnetic field. Further, the processing device 404 may be configured to determine a sensor status based on the third magnetic field and the calibration data. Further, the sensor status indicates an accuracy corresponding to each of the two or more sensors.

In some embodiments, the processing device 404 may be further configured to determine an angle of intersection based on the analyzing of the first sensor data and the second sensor data. Further, the generation of navigation data may be based on the angle of intersection.

In some embodiments, each of the first sensor and the second sensor includes two or more magnetic sensor elements in a linear configuration. Further, each of the two or more magnetic sensor elements of the first sensor may be parallel to each of the two or more magnetic sensor elements of the second sensor.

In some embodiments, the two or more magnetic sensors may be further configured to generate a sensor data based on the detection of a magnetic point proximal to the magnetic track. Further, the magnetic point may be configured to generate a third magnetic field. Further, the generation of the navigation data may be further based on the sensor data.

In some embodiments, the sensor board 402 may be on a second spatial plane. Further, the track may be on a third spatial plane. Further, the second plane and the third plane may be orthogonal.

In some embodiments, the magnetic track may be configured to emit an alternating magnetic field. Further, the magnitude of the alternating magnetic field may be based on the distance. Further, the first sensor may be configured to generate a first sensor data based on a first magnetic field strength. Further, the second sensor may be configured to generate a second data based on a second magnetic field strength. Further, the processing device 404 may be configured to generate a distance travel data based on the first sensor data and the second sensor data. Further, the distance travel data may be indicative of a distance travel by the device.

In some embodiments, the first sensor data corresponds to a first width of the magnetic track and the second sensor data corresponds to a second width of the magnetic track. Further, the generation of navigation data may be based on a criterion associated with the first width and the second width.

In some embodiments, the two or more magnetic sensors includes two or more hall-effect sensor, two or more proximity sensor, and two or more image sensor.

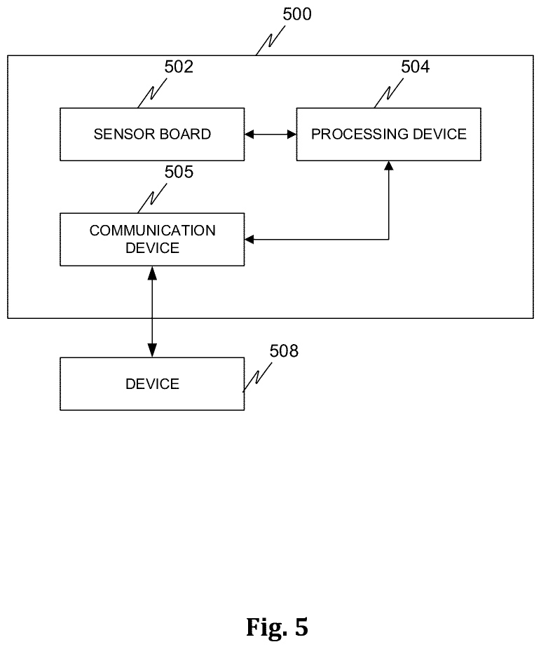

FIG. 5 illustrate a block diagram of the apparatus 500 for facilitating navigation of a device, in accordance with some embodiments.

Accordingly, the apparatus 500 may include a sensor board 502. Further, the sensor board 502 may include two or more magnetic sensors. Further, the two or more magnetic sensors includes a first sensor and a second sensor. Further, the first sensor and the second sensor may be in line on a first plane and separated by a distance. Further, the first sensor may be configured to generate a first sensor data based on monitoring of a magnetic field strength of a first magnetic field associated with a first portion of a magnetic track. Further, the second sensor may be configured to generate a second sensor data based on monitoring of the magnetic field strength of a second magnetic field associated with a second portion of the magnetic track. Further, the first portion of the magnetic track and second portion of the magnetic track may be in line along a length of the magnetic track. Further, the sensor board 502 may include an electromagnetic coil which may be configured to generate a third magnetic field proximal to each of the two or more magnetic sensors. Further, an actuation of the electromagnetic coil generate the third magnetic field. Further, the two or more magnetic sensors may be further configured to generate a calibration data based on the third magnetic field.

Further, the apparatus 500 may include a processing device 504 communicatively coupled with the sensor board 502. Further, the processing device 504 may be configured to analyze the calibration data. Further, the processing device 504 may be configured to determine a sensor status based on the analyzing of the calibration data. Further, the sensor status indicates an accuracy corresponding to each of the two or more sensors. Further, the processing device 504 may be configured to analyze the first sensor data and the second sensor data. Further, the processing device 504 may be configured to generate a navigation data based on the analyzing. Further, the navigation data determine a movement of the device in accordance with the track.

Further, the apparatus 500 may include a communication device 506 communicatively coupled with the processing device 504. Further, the communication device 506 may be configured to transmit the navigation data to the device 508.

In some embodiments, the processing device may be further configured to flag one or more of sensors of the two or more magnetic sensors for recalibration based on the sensor status.

According to some embodiments, a method of facilitating navigation of a device. Further, the method may include receiving, using a communication device, a first sensor data and a second sensor data from a sensor board. Further, the sensor board includes two or more sensors. Further, the two or more sensors include a first sensor and a second sensor. Further, the first sensor and the second sensor may be in line on a first plane and separated by a distance. Further, the first sensor may be configured to generate a first sensor data based on monitoring of a characteristic of a first portion of a track. Further, the second sensor may be configured to generate a second sensor data based on monitoring of the characteristic of a second portion of the track. Further, the first portion of the track and second portion of the track may be in line along a length of the track. Further, the method may include analyzing, using a processing device, the first sensor data and the second sensor data. Further, the method may include generating, using the processing device, a navigation data based on the analyzing. Further, the method may include transmitting, using the communication device, the navigation data to the device.

According to some embodiments, a system for facilitating navigation of a device. Further, the system may include a communication device. Further, the communication device may be configured to receive a first sensor data and a second sensor data from a sensor board. Further, the sensor board includes two or more sensors. Further, the two or more sensors include a first sensor and a second sensor. Further, the first sensor and the second sensor may be in line on a first plane and separated by a distance. Further, the first sensor may be configured to generate a first sensor data based on monitoring of a characteristic of a first portion of a track. Further, the second sensor may be configured to generate a second sensor data based on monitoring of the characteristic of a second portion of the track. Further, the first portion of the track and second portion of the track may be in line along a length of the track. Further, the communication device may be configured to transmit, a navigation data to the device. Further, the system may include a processing device communicatively coupled with the communication device. Further, the processing device may be configured to analyze, the first sensor data and the second sensor data. Further, the processing device may be configured to generate the navigation data based on the analyzing.

### Aspects:

1. A magnetic track following sensor for mobile robots, comprising two parallel rows of Hall sensors, capable of detecting both the lateral position and the angle of intersection with a magnetic track.

2. The sensor as claimed in aspect 1, wherein the angle detection capability is used to generate a steering signal based on the mechanical dimensions of the robot, allowing for anticipatory path following.

3. The sensor as claimed in aspect 1, capable of measuring the distance traveled by the robot when used with magnetic tape having alternating polarity.

4. A sensor system capable of automatically detecting and adjusting to varying track widths, comprising: a) a sensor positioned adjacent to a track to measure the track's width from both the front and rear sides; b) a control system coupled to the sensor, configured to process the front and rear width measurements and automatically adjust to the detected track width, wherein: the system compares the front and rear width measurements of the track; when the front and rear width measurements are equal, the system determines that a valid track width has been measured and adjusts the sensor configuration accordingly to account for the track's width; when there is a discrepancy between the front and rear measurements, the system identifies the track as having a non-uniform structure, and the sensor disregards the invalid width measurement for automatic adjustments.

5. The system of aspect 4, wherein the sensor's ability to automatically adjust for track width is enabled by processing the front and rear width measurements in real-time, ensuring an accurate measurement for tracks of varying widths.

6. The system of aspect 4, wherein the sensor will ignore width measurements when the front and rear widths differ beyond a predefined threshold, indicating that the track's structure is irregular or non-linear and not suitable for automatic width adjustment.

7. A method for automatically detecting and adjusting to track width, comprising: a) positioning a sensor adjacent to a track to measure the width from both the front and rear sides; b) continuously comparing the front and rear width measurements of the track; c) automatically adjusting the sensor configuration to the detected track width when the front and rear measurements are equal; d) disregarding width measurements when a discrepancy between the front and rear widths is detected, indicating an invalid measurement due to the track's irregular structure.

8. A system for self-testing Hall sensor ICs, comprising: a) a plurality of Hall sensor ICs arranged in a specified configuration; b) electromagnets positioned beneath each Hall sensor IC, each consisting of printed circuit coils that generate magnetic fields, wherein all electromagnets are activated simultaneously to generate a uniform magnetic field, wherein the Hall sensor ICs detect the generated magnetic field and compare the measured field strength to expected values, wherein the system verifies the proper operation of all Hall sensor ICs based on their ability to sense the magnetic field generated by the printed circuit coil electromagnets.

9. The system of aspect 8, wherein the printed circuit coil electromagnets are fabricated as part of the system's printed circuit board (PCB), providing a compact and integrated design for generating uniform magnetic fields across all Hall sensor ICs.

10. The system of aspect 8, wherein the Hall sensor ICs simultaneously report their detected magnetic field readings to a central control unit, which assesses the functionality and accuracy of each sensor based on deviations from expected values.

11. A method for self-testing Hall sensor ICs, comprising: a) activating all printed circuit coil electromagnets at the same time to generate a magnetic field; b) detecting the magnetic field using a plurality of Hall sensor ICs positioned above the electromagnets; c) comparing the detected magnetic field from each sensor IC to expected values; d) flagging any sensor ICs that do not detect the magnetic field or detect an incorrect value for recalibration or further investigation.

Although the invention has been explained in relation to its preferred embodiment, it is to be understood that many other possible modifications and variations can be made without departing from the spirit and scope of the invention as hereinafter claimed.

What is claimed is:

1. An apparatus for facilitating navigation of a device, the apparatus comprises:
a sensor board comprising a plurality of sensors, wherein the plurality of sensors comprises a first sensor and a second sensor, wherein the first sensor and the second sensor are in line on a first plane and separated by a distance, wherein the first sensor is configured to generate a first sensor data based on monitoring of a characteristic of a first portion of a track, wherein the second sensor is configured to generate a second sensor data based on monitoring of the characteristic of a second portion of the track, wherein the first portion of the track and second portion of the track are in line along a length of the track;
a processing device communicatively coupled with the sensor board, wherein the processing device is configured to:
analyze the first sensor data and the second sensor data;
generate a navigation data based on the analyzing, wherein the navigation data determine a movement of the device in accordance with the track; and
a communication device communicatively coupled with the processing device, wherein the communication device is configured to transmit the navigation data to the device.

2. The apparatus of claim 1, wherein the processing device is further configured to determine an angle of intersection based on the analyzing of the first sensor data and the second sensor data, wherein the generation of navigation data is based on the angle of intersection.

3. The apparatus of claim 1, wherein each of the first sensor and the second sensor comprises a plurality of sensor elements in a linear configuration, wherein each of the plurality of sensor elements of the first sensor is parallel to each of the plurality of sensor elements of the second sensor.

4. The apparatus of claim 1, wherein the first sensor comprises a first magnetic sensor and the second sensor comprises a second magnetic sensor, wherein the track comprises of a magnetic track configured to emit a magnetic field, wherein the first magnetic and the second magnetic are configured to monitor the characteristic of the track based on the magnetic field emitted by the track.

5. The apparatus of claim 1, wherein the plurality of sensors is further configured to generate a sensor data based on detection of a track point proximal to the track, wherein the track point comprises a unique characteristic, wherein the generation of the navigation data is further based on the sensor data.

6. The apparatus of claim 1, wherein sensor board is on a second spatial plane, wherein the track is on a third spatial plane, wherein the second plane and the third plane are orthogonal.

7. The apparatus of claim 1, wherein each of the first sensor and the second sensor comprises a magnetic sensor, wherein the track comprises a magnetic track configured to emit an alternating magnetic field, wherein the magnitude of the alternating magnetic field is based on the distance, wherein the first sensor is configured to generate first sensor data based on a first magnetic field strength, wherein the second sensor is configured to generate the second sensor data based on a second magnetic field strength, wherein the processing device is configured to generate a distance travel data based on the first sensor data and the second sensor data, wherein the distance travel data is indicative of a distance traveled by the device.

8. The apparatus of claim 1, wherein the plurality of sensors comprises a plurality of optical sensors, wherein the track comprises an optical characteristic, wherein the plurality of optical sensors is configured to monitor the optical characteristic.

9. The apparatus of claim 1, wherein the first sensor data corresponds to a first width of the track and the second sensor data corresponds to a second width of the track, wherein the generation of navigation data is based on a criterion associated with the first width and the second width.

10. The apparatus of claim 1, wherein the processing device is further configured to determine a lateral position of the device in relation to the track based on the analysis, wherein the generation of the navigation data is based on the lateral position.

11. An apparatus for facilitating navigation of a device, the apparatus comprises:
a sensor board comprising a plurality of magnetic sensors, wherein the plurality of magnetic sensors comprises a first sensor and a second sensor, wherein the first sensor and the second sensor are in line on a first plane and separated by a distance, wherein the first sensor is configured to generate a first sensor data based on monitoring of a magnetic field strength of a first magnetic field associated with a first portion of a magnetic track, wherein the second sensor is configured to generate a second sensor data based on monitoring of the magnetic field strength of a second magnetic field associated with a second portion of the magnetic track, wherein the first portion of the magnetic track and second portion of the magnetic track are in line along a length of the magnetic track;
a processing device communicatively coupled with the sensor board, wherein the processing device is configured to:
analyze the first sensor data and the second sensor data;
generate a navigation data based on the analyzing, wherein the navigation data determine a movement of the device in accordance with the track; and
a communication device communicatively coupled with the processing device, wherein the communication device is configured to transmit the navigation data to the device.

12. The apparatus of claim 11, wherein the sensor board further comprises an electromagnetic coil configured to generate a third magnetic field proximal to each of the plurality of sensors, wherein an actuation of the electromagnetic coil generates the third magnetic field, wherein the plurality of sensors is further configured to generate a calibration data based on the third magnetic field, wherein the processing device is configured to:
analyze the calibration data;
determine a sensor status based on the calibration data, wherein the sensor status indicates an accuracy corresponding to each of the plurality of sensors.

13. The apparatus of claim 11, wherein the processing device is further configured to determine an angle of intersection based on the analyzing of the first sensor data and the second sensor data, wherein the generation of navigation data is based on the angle of intersection.

14. The apparatus of claim 11, wherein each of the first sensor and the second sensor comprises a plurality of magnetic sensor elements in a linear configuration, wherein each of the plurality of magnetic sensor elements of the first sensor is parallel to each of the plurality of magnetic sensor elements of the second sensor.

15. The apparatus of claim 11, wherein the plurality of magnetic sensors is further configured to generate a sensor data based on the detection of a magnetic point proximal to the magnetic track, wherein the magnetic point is configured to generate a third magnetic field, wherein the generation of the navigation data is further based on the sensor data.

16. The apparatus of claim 11, wherein sensor board is on a second spatial plane, wherein the track is on a third spatial plane, wherein the second plane and the third plane are orthogonal.

17. The apparatus of claim 11, wherein the track comprises a magnetic track configured to emit an alternating magnetic field, wherein the magnitude of the alternating magnetic field is based on the distance, wherein the first sensor is configured to generate a first sensor data based on a first magnetic field strength, wherein the second sensor is configured to generate a second data based on a second magnetic field strength, wherein the processing device is configured to generate a distance travel data based on the first sensor data and the second sensor data, wherein the distance travel data is indicative of a distance traveled by the device.

18. The apparatus of claim 11, wherein the first sensor data corresponds to a first width of the magnetic track and the second sensor data corresponds to a second width of the magnetic track, wherein the generation of navigation data is based on a criterion associated with the first width and the second width.

19. The apparatus of claim 11, wherein the plurality of magnetic sensors comprises a plurality of hall-effect sensors.

20. An apparatus for facilitating navigation of a device, the apparatus comprises:
a sensor board comprises:
a plurality of magnetic sensors, wherein the plurality of magnetic sensors comprises a first sensor and a second sensor, wherein the first sensor and the second sensor are in line on a first plane and separated by a distance, wherein the first sensor is configured to generate a first sensor data based on monitoring of a magnetic field strength of a first magnetic field associated with a first portion of a magnetic track, wherein the second sensor is configured to generate a second sensor data based on monitoring of the magnetic field strength of a second magnetic field associated with a second portion of the magnetic track, wherein the first portion of the magnetic track and second portion of the magnetic track are in line along a length of the magnetic track;
an electromagnetic coil configured to generate a third magnetic field proximal to each of the plurality of magnetic sensors, wherein an actuation of the electromagnetic coil generate the third magnetic field, wherein the plurality of magnetic sensors is further configured to generate a calibration data based on the third magnetic field;
a processing device communicatively coupled with the sensor board, wherein the processing device is configured to:
analyze the first sensor data, the second sensor data, and the calibration data;
determine a sensor status based on the analyzing of the calibration data, wherein the sensor status indicates an accuracy corresponding to each of the plurality of magnetic sensors;
generate a navigation data based on the analyzing, wherein the navigation data determine a movement of the device in accordance with the track; and
a communication device communicatively coupled with the processing device, wherein the communication device is configured to transmit the navigation data to the device.
